(19) United States
(12) Patent Application Publication
(10) Pub. No.: US 2006/0216887 A1
(43) Pub. Date: Sep. 28, 2006

(54) THE MEMORY CELL AND CELL ARRAY FOR EMBEDDED SYSTEM

(75) Inventors: PingFu Hsieh, Tainan (TW); HungJu Wang, Tainan (TW); TsaiHeng Su, Tainan (TW); ChihChe Cheng, Tainan (TW)

Correspondence Address: BEEDAR TECHNOLOGY INC., R206, #12, NAN-KE 2ND ROAD,, TAINAN SCIENCE-BASED INDUSTRIAL PARK, TAINAN, TW

(73) Assignee: BEEDAR TECHNOLOGY INC., Tainan (TW)

(21) Appl. No.: 10/907,219

(22) Filed: Mar. 24, 2005

(51) Int. Cl. G11C 11/34

(52) U.S. Cl. 438/257

(57) ABSTRACT

In the present applications of electronic products, nonvolatile memory such as EEPROM and flash is employed widely for data storage. However, traditional nonvolatile memory needs specific process to be fabricated in foundries so that the integration shows difficulty among nonvolatile memory, analog, and digital portions. Thus, the invention is issued to provide the creative method for generic monolithic CMOS process in foundries, to be integrated into the system conveniently, and to advance the time to market. The structure and operation of cell and cell array is interpreted as following.

### FIELD OF THE INVENTION

This invention can be applied in nonvolatile embedded EEPROM (Electrically Erasable and Programmable Read Only Memory) and embedded Flash memory. The most important feature of invention is cell can be made by conventional CMOS process instead of specific memory process.

### BACKGROUND OF THE INVENTION

In the present applications of electronic products, nonvolatile memory is widely employed for data storage. Especially in the more and more popular trend of SOC (system on chip), It provides lower cost and better reliability for systems. Traditionally nonvolatile memory needs special process to be fabricated in foundries, different from logic, or others. Therefore, extra cost would be generated when manufacturing. According the idea, the invention provides the creative method for generic monolithic CMOS process in foundries, to reduce manufacturing cost effectively, and to be integrated into the system conveniently.

### SUMMARY OF THE INVENTION

The present invention is a creative way to design a nonvolatile semiconductor memory and embedded memory for any electronic products and embedded systems nowadays. It has several advantages for handy utilization as following:

1. It is fabricated in generic semiconductor CMOS process to save the cost effectively. At the same time, program/erase cycles and data retention still keep reliable.

2. Bit-based or block-based operation makes memory array more flexible applications, depends on marketing and product requirements.

3. Lower program/erase voltage needed than others eases the analog front end design, reduces power consumption of systems, and fits for MOS devices of generic process.

4. Only two layers are utilized to save the usage of metal for other interconnections or to be low cost design for the process with limited metal layers.

### BRIEF DESCRIPTION OF THE DRAWINGS

FIG. 1A, 1B, 1C, and 1D illustrate the circuit representative, the top view of layout, the cross-section views based upon two orthogonal directions of BeeDar in-house FLOTOX EEPROM cell with generic CMOS process. The transistor is an n-channel device with its control gate connected to the control signal, CG, drain connected to the bit line, BL, and source connected to the array ground, AG.

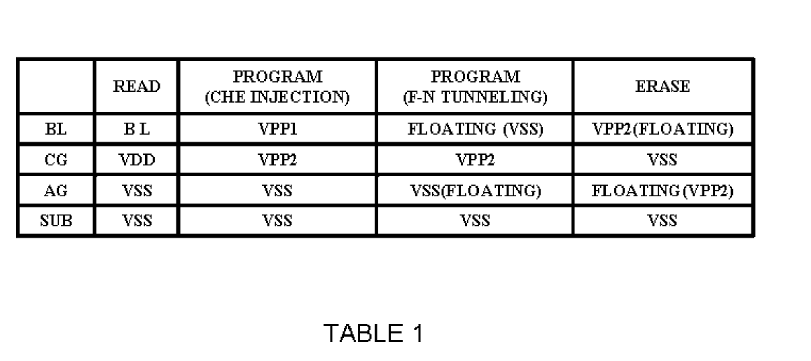

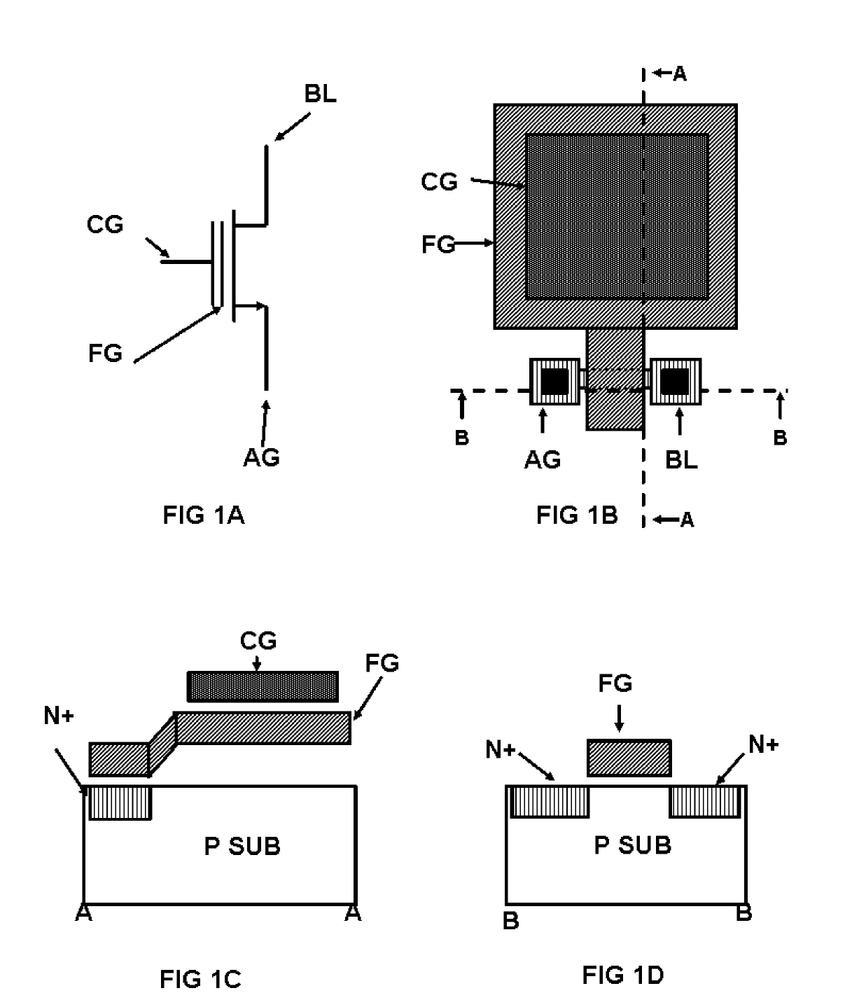

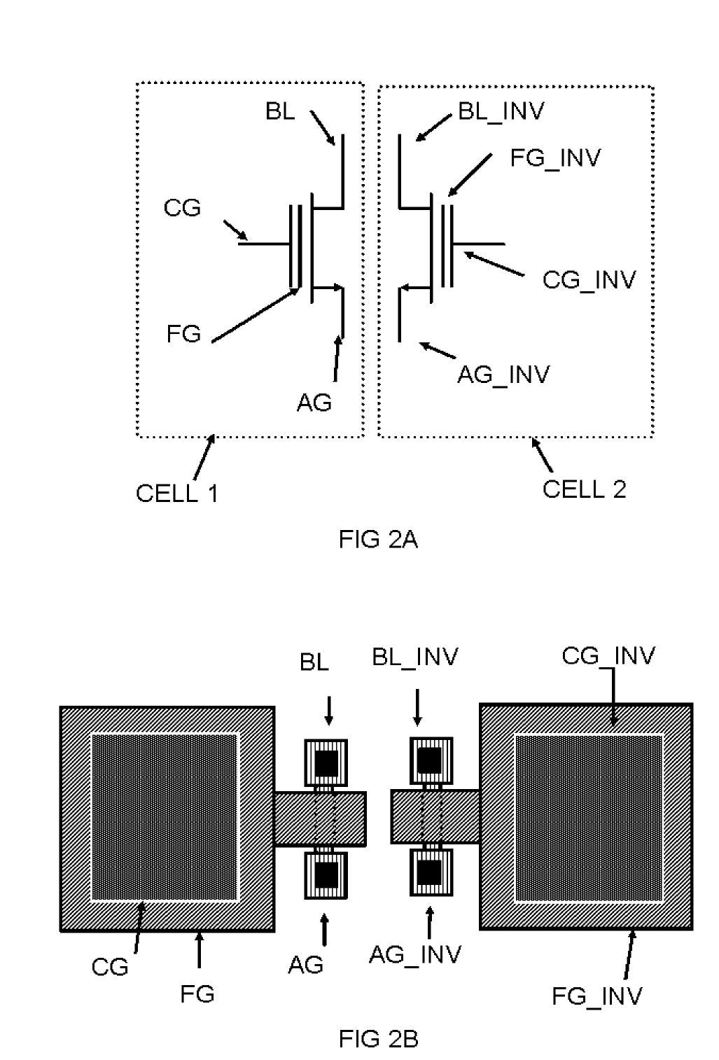

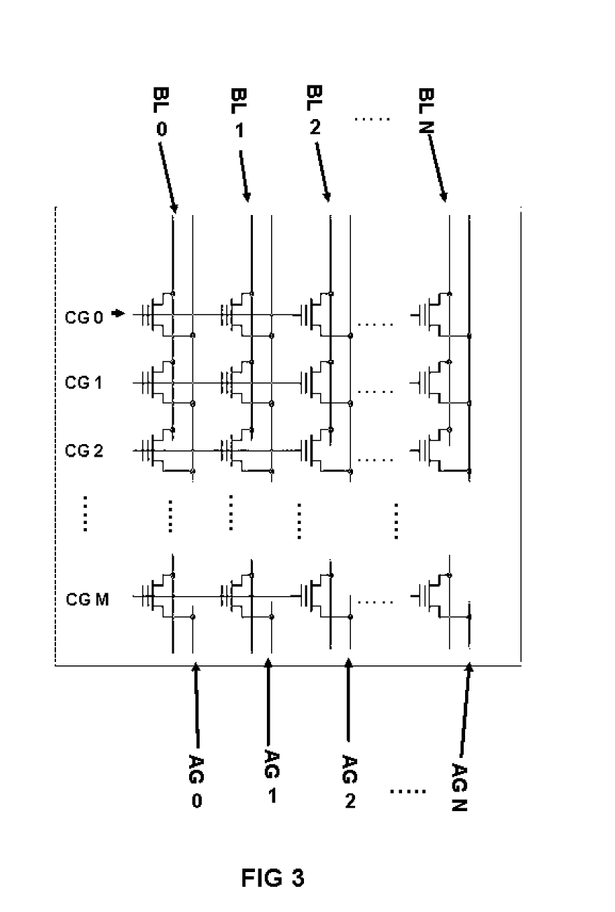

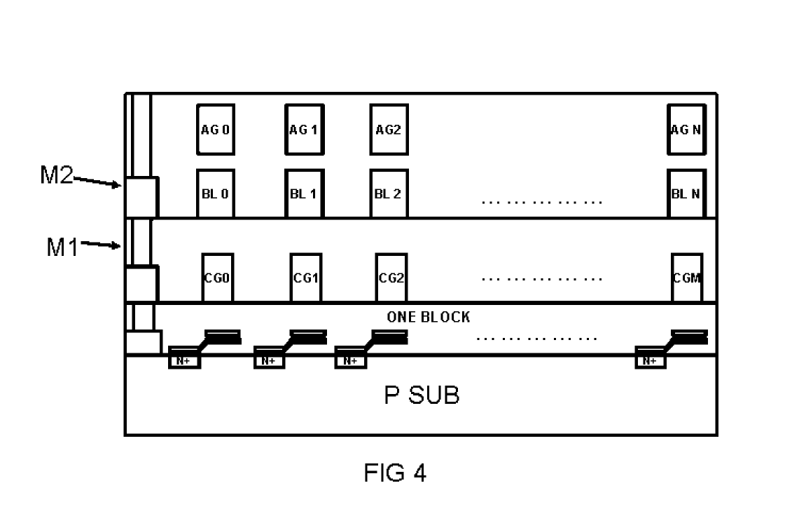

The double poly nonvolatile memory cell is composed of two parts, i.e. coupling capacitor and MOS device. The former, as FIG. 1C, is fabricated by double poly layer and dielectric interlayer. According to the MOS device in FIG. 1D, the tunneling oxide is formed between floating gate and substrate with conventional CMOS process. No extra mask or special process is needed. The coupling ratio is estimated around 0.73, and the higher is more preferred with larger area of coupling capacitor with respect to the one of MOS device.

Table 1 characterizes the operations of BeeDar's FLOTOX EEPROM cell. The three operations have unique terminal conditions individually. Moreover, two program mechanisms of channel hot electron (CHE) injection and Fowler-Nordheim (F-N) tunneling are provided to select. It depends on the requirements of speed, current consumption, complexity of control circuit . . . . etc. There are two cases to be chosen for Fowler-Nordheim (F-N) tunneling in either program or erase operation.

FIG. 2A and 2B illustrate the circuit representative, and the top view of layout of one bit of BeeDar in-house FLOTOX EEPROM cells with generic CMOS process. The transistor is an n-channel device with its control gate connected to the control signal, CG, drain connected to the bit line, BL, and source connected to the array ground, AG. The other one is the mirror of the former. It is an n-channel device with its control gate connected to the control signal, CG_INV, drain connected to the bit line, BL_INV, and source connected to the array ground, AG_INV. The operations between them are just opposite so that their control signal is independent. The pair of cells characterize one bit of data, in contrast to the single cell with reference to the global one.

FIG. 3 illustrates the circuit of double poly nonvolatile memory array of M×N scale. The cells can be operated bit by bit or block by block. Moreover, their operation mechanism is designed to use channel hot electron (CHE) injection or Fowler-Nordheim (F-N) tunneling for program and Fowler-Nordheim (F-N) tunneling for erase. They should be controlled well by peripheral devices and digital logic.

FIG. 4 illustrates the cross sectional view of metal lines of memory cell array. Only two layers are utilized to save the usage of metal. The group of CG lines is arranged in the lowest metal, M1. The groups of AG and BL lines are designed in the second metal, M2.

### DETAILED DESCRIPTION OF A PREFERRED EMBODIMENT

FIG. 1A, 1B, 1C, and 1D illustrate the circuit representative, the top view of layout, the cross-section views based upon two orthogonal directions of BeeDar in-house FLOTOX EEPROM cell with generic CMOS process. The transistor is an n-channel device with its control gate connected to the control signal, CG, drain connected to the bit line, BL, and source connected to the array ground, AG.

The double poly nonvolatile memory cell is composed of two parts, i.e. coupling capacitor and MOS device. The former, as FIG. 1C, is fabricated by double poly layer and dielectric interlayer. According to the MOS device in FIG. 1D, the tunneling oxide is formed between floating gate and substrate with conventional CMOS process. No extra mask or special process is needed. The thickness is designed to be around 70A and that will provide the two tunneling mechanisms for program and erase operations when proper voltages are applied to its terminals.

Table 1 characterizes the operations of BeeDar's FLOTOX EEPROM cell. The charges in floating gate directly influence the threshold voltage of double-gate device. When no charge exists in the floating gate, the threshold is low, meaning that a significant current may flow between source and drain if a high voltage is applied on the gate. In contrast, when charges are trapped in the floating gate, the threshold voltage is high, almost no current flows through the device, independent of the gate voltage.

In read operation, low voltage Vdd of 1.5V is imposed on the control gate (CG) and OV on array control (AG) and substrate (SUB). Please refer to the FIG. 1A. Then the induced current or no current occurs on bit line (BL) if the cell is charged or discharged respectively.

In program operation, the mechanism of channel hot electron (CHE) injection is utilized to charge BeeDar's nonvolatile memory. Please refer to the FIG. 1A. The source is applied to VSS. The high drain voltage 6V (VPP1) generates a large electric field to shift the energy distribution of carriers higher. That gives rise to hot electrons happened. On the other hand, the ultra high control gate voltage 8V (VPP2) attracts some of hot electrons to floating gate through the thin tunneling oxide.

Another mechanism of Fowler-Nordheim (F-N) tunneling could be also employed to program the double poly nonvolatile memory. The control gate is connected to 8V (VPP2) and the source to VSS (or floating). The drain is connected floating (or VSS). Electrons are pulled up to the floating gate because of the induced high electrical field between them.

In erase operation, the mechanism of Fowler-Nordheim (F-N) tunneling is used to discharge our EEPROM. Please see FIG. 1A. The control gate is connected to VSS and the drain is applied to the high voltage 8V, VPP2 (or floating). The source is connected floating (or VPP2). Electrons are pulled off the floating gate because of the induced high electrical field between them.

FIG. 2A, and 2B illustrate the circuit representative, and the top view of layout of BeeDar in-house FLOTOX EEPROM cells of one bit with generic CMOS process. The transistor is an n-channel device with its control gate connected to the control signal, CG, drain connected to the bit line, BL, and source connected to the array ground, AG. The other one is the mirror of the former. It is an n-channel device with its control gate connected to the control signal, CG_INV, drain connected to the bit line, BL_INV, and source connected to the array ground, AG_{'}INV. The independent sets of control signal secure the pair of cells to operate oppositely. For example, the left cell in FIG. 2A is charged to be program mode; the right one is discharged to be erase mode, and vice versa.

The pair of cells in FIG. 2B characterize one bit of data, in contrast to the single cell with reference to the global one which provides the global reference level to be compared with threshold voltage of EEPROM cell to be data 1 or 0.

FIG. 3 illustrates the circuit of double poly nonvolatile memory array of M×N scale. The cells can be operated bit by bit if the peripheral control circuit and digital logic serve all cells independently as the mentioned above. When cell [0, 0] is selected to be read, for example, CG [0, 0] is applied to VDD, AG [0, 0] to VSS, and the induced current occurs at BL [0, 0] to be read. The others are pulled-up or pulled-down. The program and erase operations of cell array could be referred to the single cell in the same way.

They can be also operated block by block if the peripheral control circuit and digital logic serve the cells of one block at the same time. For instance, when cell [0, 0] is selected to be read, CG 0 in the row is applied to VDD, AG 0 in the column to VSS, and the induced current from the cell occurs at BL 0 in the column to be read. The other CG lines keep at VSS and the other AG lines stay floating so that the other cells still maintain silent. The program and erase operations of cell array could be referred to the single cell in the same way.

According to their operation mechanism, read mode is straightforward, program mode is able to be chosen to use channel hot electron (CHE) injection or Fowler-Nordheim (F-N) tunneling, and erase mode uses Fowler-Nordheim (F-N) tunneling only. They should be selected and controlled well by peripheral devices and digital logic.

FIG. 4 illustrates the cross sectional view of metal lines of memory cell array. Only two layers are utilized to save the usage of metal for other interconnections or to be low cost design for the process with limited metal layers. The group of CG lines is arranged in the lowest metal, M1. The groups of AG and BL lines are designed in the second metal, M2.

What is claimed is:

1. A method of designing and fabricating non-volatile memory comprising:
a physical structure of N-transistor or P-transistor EEPROM cells in generic monolithic CMOS process.
an array structure of N-transistor or P-transistor EEPROM cells in generic monolithic CMOS process.

2. The method according to claim 1 wherein said EEPROM cells are formed in p substrate.

3. The method according to claim 1 wherein said EEPROM cells are formed in n substrate with p-well.

4. The method according to claim 1 wherein said EEPROM cells are formed in double poly with only two metal needed, and generic monolithic CMOS process.

5. The method according to claim 1 wherein said EEPROM cells are operated at lower program and erase voltages.

6. The method according to claim 1 wherein said EEPROM cells with larger area ratio of the control gate and floating gate to the fixed transistor have higher efficiency in operations.

7. A structure of non volatile memory of one bit comprising:
a structure of a single cell with reference to the global one;
a structure of a pair of cells with opposite operation;
an array structure of N-transistor or P-transistor EEPROM cells in generic monolithic CMOS process.

8. The method according to claim 7 wherein said EEPROM global cell is designed to provides the global reference level to be compared with threshold voltage of EEPROM cell to be data 1 or 0.

9. The method according to claim 7 wherein said a pair of EEPROM cells represent data 1 or 0 when one of them is charged (or discharged) and the other is discharged (or charged).

10. The method according to claim 7 wherein said a pair of EEPROM cells are formed in all four combinations of N-channel and P-channel transistors, namely N-N, P-P, N-P, and P-N.

11. The method according to claim 1 wherein said one bit of EEPROM cells could be used flexibly by either a single bit operation or a block of bits operation.

12. The method according to claim 1 wherein said EEPROM arrays composed of EEPROM cells could be utilized in arbitrary scales.

13. The method according to claim 1 wherein said one bit of EEPROM cells and EEPROM arrays could be used in applications of PC peripherals, communication, consumer products, embedded systems, and all other applicable fields.

14. The method according to claim 7 wherein said one bit of EEPROM cells could be operated flexibly by either bit or block.

15. The method according to claim 7 wherein said EEPROM arrays composed of EEPROM cells could be utilized in arbitrary scales.

16. The method according to claim 7 wherein said one bit of EEPROM cells and EEPROM arrays could be used in applications of PC peripherals, communication, consumer products, embedded systems, and all other applicable fields.
